(19) United States
(12) Patent Application Publication
(10) Pub. No.: US 2026/0164784 A1
(43) Pub. Date: Jun. 11, 2026

(54) BACKSIDE GATE CONTACT FOR SHIFTED STACKED FETS

(71) Applicant: INTERNATIONAL BUSINESS MACHINES CORPORATION, Armonk, NY (US)

(72) Inventors: Debarghya Sarkar, Latham, NY (US); Ruilong Xie, Niskayuna, NY (US); Chen Zhang, Santa Clara, CA (US); Nicholas Anthony Lanzillo, Wynantskill, NY (US); James Patrick Mazza, Saratoga Springs, NY (US); Takashi Ando, Eastchester, NY (US); Brent Alan Anderson, Jericho, VT (US); Shay Reboh, Guilderland, NY (US)

(21) Appl. No.: 18/975,523

(22) Filed: Dec. 10, 2024

(51) Int. Cl. H10D 84/85; H10D 30/00; H10D 62/10; H10D 64/23; H10D 64/27

(52) U.S. Cl. CPC H10D 84/851; H10D 64/254; H10D 64/512; H10D 84/856; H10D 30/501; H10D 62/121

(57) ABSTRACT

A semiconductor device includes a lower device layer having a bottom transistor and an upper device layer having a transistor, positioned above and laterally offset from the bottom transistor. A backside power plane is below the lower device layer. A backside bottom gate contact penetrates through the backside power plane to contact a gate of the bottom transistor. A dielectric liner is between the backside power plane and the backside bottom gate contact.

### BACKGROUND

The present invention generally relates to semiconductor devices and, more particularly, to semiconductor devices with backside gate contacts.

Field effect transistors (FETs) can be stacked over one another to increase the areal device density of an integrated circuit. Forming contacts to such devices can be challenging, as the contacts to a transistor on one level may be formed in close proximity to a transistor on the other level.

### SUMMARY

A semiconductor device includes a lower device layer having a bottom transistor and an upper device layer having a transistor, positioned above and laterally offset from the bottom transistor. A backside power plane is below the lower device layer. A backside bottom gate contact penetrates through the backside power plane to contact a gate of the bottom transistor. A dielectric liner is between the backside power plane and the backside bottom gate contact.

A semiconductor device includes a lower device layer having a bottom transistor and an upper device layer having a top transistor positioned above and laterally offset from the bottom transistor. A first backside interlayer dielectric is below the lower device layer. A backside power plane is below the first backside interlayer dielectric. A backside bottom gate contact penetrates through the backside power plane and the first backside interlayer dielectric to contact a gate of the bottom transistor. A dielectric liner is directly between the backside power plane and the backside bottom gate contact.

A semiconductor device includes a lower device layer having a bottom transistor and an upper device layer having a top transistor, positioned above and laterally offset from the bottom transistor. A backside interlayer dielectric is below the lower device layer. A backside power plane is below the backside interlayer dielectric. A backside bottom gate contact penetrates through the backside power plane and the first backside interlayer dielectric to contact a gate of the bottom transistor. A backside top S/D contact penetrates through the backside power plane to contact a source/drain structure of the top transistor. A dielectric liner is directly between the backside power plane and the backside bottom gate contact.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a semiconductor device that illustrates the relative positions of a set of cross-sectional planes, in accordance with an embodiment of the present invention;

FIG. 2 is a set of cross-sectional views of a step in the fabrication of a semiconductor device, showing the formation of a lower device layer that includes bottom field effect transistors (FETs), in accordance with an embodiment of the present invention;

FIG. 3 is a set of cross-sectional views of a step in the fabrication of a semiconductor device, showing the formation of a stack of alternating semiconductor layers above the lower device layer, in accordance with an embodiment of the present invention;

FIG. 4 is a set of cross-sectional views of a step in the fabrication of a semiconductor device, showing the formation of an upper device layer that includes top FETs from the stack of alternating semiconductor layers, in accordance with an embodiment of the present invention;

FIG. 5 is a set of cross-sectional views of a step in the fabrication of a semiconductor device, showing the removal of a substrate and formation of a first backside interlayer dielectric, in accordance with an embodiment of the present invention;

FIG. 6 is a set of cross-sectional views of a step in the fabrication of a semiconductor device, showing the formation of a backside power plane with backside bottom contact, in accordance with an embodiment of the present invention;

FIG. 7 is a set of cross-sectional views of a step in the fabrication of a semiconductor device, showing the formation of a backside gate via and liner that penetrates through the backside power plane, in accordance with an embodiment of the present invention;

FIG. 8 is a set of cross-sectional views of a step in the fabrication of a semiconductor device, showing the formation of a backside top contact via and backside bottom gate via, in accordance with an embodiment of the present invention;

FIG. 9 is a set of cross-sectional views of a step in the fabrication of a semiconductor device, showing the formation of backside gate contact and backside top contact, in accordance with an embodiment of the present invention; and

FIG. 10 is a block/flow diagram of a method of forming a semiconductor device having shifted stacked FETs, in accordance with an embodiment of the present invention.

### DETAILED DESCRIPTION

Conductive contacts can be formed to the gate of field effect transistors (FETs) in a semiconductor device with stacked FETs that are shifted with respect to one another. Backside gate contacts may be formed by etching through a backside power plane and forming a via with a dielectric liner to isolate the backside gate contacts from the power plane and other backside contacts.

According to an aspect of the invention, there is provided a semiconductor device that includes a lower device layer having a bottom transistor and an upper device layer having a transistor, positioned above and laterally offset from the bottom transistor. A backside power plane is below the lower device layer. A backside bottom gate contact penetrates through the backside power plane to contact a gate of the bottom transistor. A dielectric liner is between the backside power plane and the backside bottom gate contact. The backside bottom gate contact provides access to the bottom transistor in a manner that avoids risking short-circuits to structures of the top transistor, while the dielectric liner provides electrical insulation between the backside bottom gate contact and the backside power plane.

In embodiments, the semiconductor device includes a backside bottom source/drain (S/D) contact that electrically connects the backside power plane to a source/drain structure of the bottom transistor. The backside bottom S/D contact further provides access to the bottom transistor for power connections.

In embodiments, the dielectric liner directly contacts the backside bottom gate contact and the backside bottom S/D contact. The dielectric liner thereby provides electrical insulation between the backside bottom gate contact and the backside bottom S/D contact as well.

In embodiments, the semiconductor device includes a backside top S/D contact that penetrates through the backside power plane to contact a source/drain structure of the top transistor. The backside top S/D contact provides access to the top transistor.

In embodiments, the semiconductor device includes a bonding layer between the lower device layer and the upper device layer. The backside top S/D contact penetrates the lower device layer and the bonding layer. The bonding layer may remain from the fabrication of the upper device layer and so the backside top S/D contact penetrates that layer to reach the upper device layer.

In embodiments, the semiconductor device includes a first backside interlayer dielectric between the lower device layer and the backside power plane. This interlayer dielectric electrically insulates the backside power plane from the gate of the bottom transistor.

In embodiments, the backside bottom gate contact directly contacts the first backside interlayer dielectric in a region between the dielectric liner and the gate of the bottom transistor. This exposed portion of the first backside interlayer dielectric is a remnant of the formation of the backside bottom gate contact that is used to prevent etching a bottom surface of the bottom gate.

In embodiments, the semiconductor device includes a second backside interlayer dielectric below the backside power plane, formed from a material that is different from a material of the first backside interlayer dielectric. The second backside interlayer dielectric provides etch selectivity during fabrication to control structure placement.

In embodiments, wherein the dielectric liner is formed from a material that is different from a material of the first backside interlayer dielectric. The material selection provides etch selectivity to preserve the dielectric liner while an etch is performed to expose a back side of the bottom gate.

According to an aspect of the invention, there is provided a semiconductor device that includes a lower device layer having a bottom transistor and an upper device layer having a top transistor positioned above and laterally offset from the bottom transistor. A first backside interlayer dielectric is below the lower device layer. A backside power plane is below the first backside interlayer dielectric. A backside bottom gate contact penetrates through the backside power plane and the first backside interlayer dielectric to contact a gate of the bottom transistor. A dielectric liner is directly between the backside power plane and the backside bottom gate contact. The backside bottom gate contact provides access to the bottom transistor in a manner that avoids risking short-circuits to structures of the top transistor, while the dielectric liner provides electrical insulation between the backside bottom gate contact and the backside power plane.

In embodiments, the semiconductor device includes a backside bottom S/D contact that electrically connects the backside power plane to a source/drain structure of the bottom transistor. The backside bottom S/D contact further provides access to the bottom transistor for power connections.

In embodiments, the dielectric liner directly contacts the backside bottom S/D contact. The dielectric liner thereby provides electrical insulation between the backside bottom gate contact and the backside bottom S/D contact as well.

In embodiments, the semiconductor device includes a backside top S/D contact that penetrates through the backside power plane to contact a source/drain structure of the top transistor. The backside top S/D contact provides access to the top transistor.

In embodiments, the semiconductor device includes a bonding layer between the lower device layer and the upper device layer. The backside top S/D contact penetrates the lower device layer and the bonding layer. The bonding layer may remain from the fabrication of the upper device layer and so the backside top S/D contact penetrates that layer to reach the upper device layer.

In embodiments, the backside bottom gate contact directly contacts the first backside interlayer dielectric in a region between the dielectric liner and the gate of the bottom transistor. This exposed portion of the first backside interlayer dielectric is a remnant of the formation of the backside bottom gate contact that is used to prevent etching a bottom surface of the bottom gate.

In embodiments, the semiconductor device includes a second backside interlayer dielectric below the backside power plane, formed from a material that is different from a material of the first backside interlayer dielectric. The second backside interlayer dielectric provides etch selectivity during fabrication to control structure placement.

In embodiments, the dielectric liner is formed from a material that is different from a material of the first backside interlayer dielectric. The material selection provides etch selectivity to preserve the dielectric liner while an etch is performed to expose a back side of the bottom gate.

According to an aspect of the invention, there is provided a semiconductor device that includes a lower device layer having a bottom transistor and an upper device layer having a top transistor, positioned above and laterally offset from the bottom transistor. A backside interlayer dielectric is below the lower device layer. A backside power plane is below the first backside interlayer dielectric. A backside bottom gate contact penetrates through the backside power plane and the first backside interlayer dielectric to contact a gate of the bottom transistor. A backside top S/D contact penetrates through the backside power plane to contact a source/drain structure of the top transistor. A dielectric liner is directly between the backside power plane and the backside bottom gate contact. The backside bottom gate contact provides access to the bottom transistor in a manner that avoids risking short-circuits to structures of the top transistor, while the dielectric liner provides electrical insulation between the backside bottom gate contact and the backside power plane.

In embodiments, the semiconductor device includes a bonding layer between the lower device layer and the upper device layer, wherein the backside top S/D contact penetrates the lower device layer and the bonding layer. The bonding layer may remain from the fabrication of the upper device layer and so the backside top S/D contact penetrates that layer to reach the upper device layer.

In embodiments, the backside bottom gate contact directly contacts the backside interlayer dielectric in a region between the dielectric liner and the gate of the bottom transistor. This exposed portion of the first backside interlayer dielectric is a remnant of the formation of the backside bottom gate contact that is used to prevent etching a bottom surface of the bottom gate.

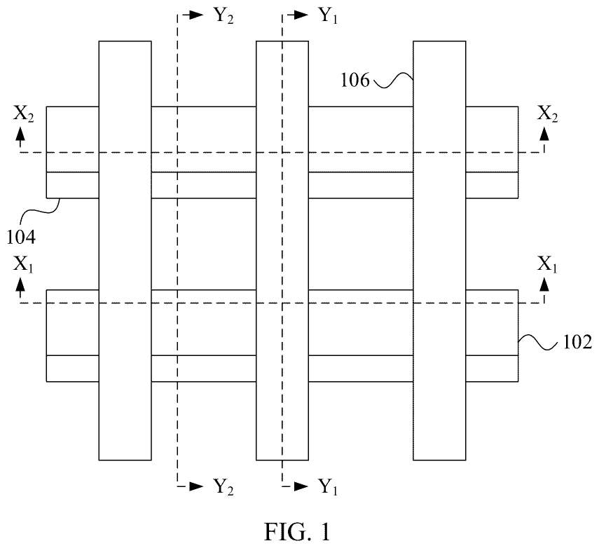

Referring now to FIG. 1, a top-down view of a semiconductor device is shown, including shifted stacked FETs. The top-down view shows top FET channels 102 and bottom FET channels 104, being laterally shifted with respect to one another such that there is a region of overlap and a region where each bottom FET channel 104 is partially exposed next to the respective top FET channel 102.

The top-down view indicates a set of cross-sectional planes that will be shown with greater detail in the following drawings. These include a cross-section X₁X₁ that cuts parallel along both a top FET channel 102 and a bottom FET channel 104 in a region of overlap, a cross-section X₂X₂ that cuts parallel along a top FET channel 102 in a region where the two FET channels do not overlap, a cross-section Y₁Y₁ that cuts perpendicular to the FET channels through a gate 106, and a cross-section Y₂Y₂ that cuts perpendicular to the FET channels in a region between adjacent gates 106.

It should be understood that the arrangement of the top FET channels, the bottom FET channels 104, and the gates 106 is provided solely for the sake of illustration and should not be seen as limiting. The following figures are not necessarily at the same scale as the elements shown in FIG. 1, nor should they be seen as being limiting in terms of size, proportion, or relative positioning of the depicted elements.

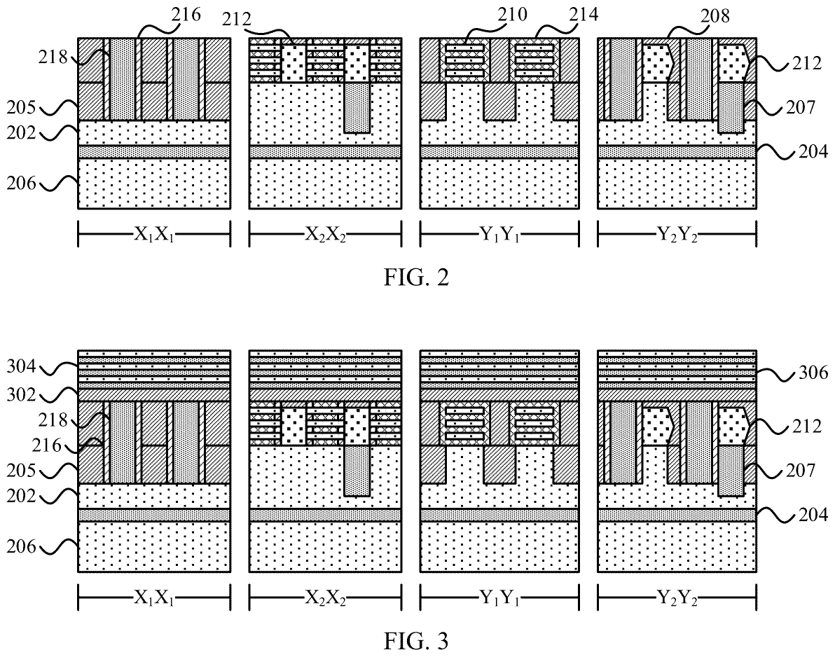

Referring now to FIG. 2, a set of cross-sectional views is shown of a step in the fabrication of shifted stacked FETs. A bottom FET layer is formed on a semiconductor substrate 202. The semiconductor substrate is itself formed on a carrier substrate 206, with an etch stop layer 204 between them.

The semiconductor substrate 202 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. The etch stop layer 204 may be, for example, a semiconductor material having etch selectivity with respect to the semiconductor substrate 202, for example silicon germanium alloys of different molar ratios when silicon is used in the semiconductor substrate 202 and the carrier substrate 206.

Shallow trench isolation (STI) structures 205 are formed in the semiconductor substrate 202, for example by etching trenches into the semiconductor substrate 202 and filling the trenches with dielectric material, such as silicon dioxide. Backside bottom contact placeholder 207 is similarly formed in the semiconductor substrate 202, but may be formed from a selectively etchable material such as silicon germanium alloy.

A set of bottom channel layers 210 are formed over the semiconductor substrate 202, for example by epitaxially growing a set of alternating layers of channel material and sacrificial material. The channel material may be silicon, for example, and the sacrificial material may be a material that is crystallographically compatible with silicon, such as silicon germanium. Bottom S/D structures 212 can be epitaxially grown from side surfaces of the bottom channel layers 210. Because silicon germanium can be selectively etched with respect to silicon, the sacrificial layers can be etched away after the formation of inner spacers to leave the bottom channel layers 210 suspended from the bottom S/D structures 212. A bottom gate stack 214 can then be formed on and around the bottom channel layers 210. A bottom interlayer dielectric 208 is formed around the bottom channel layers 210 and bottom S/D structures 212, for example using silicon dioxide and/or silicon nitride.

The bottom gate stack 214 may include a gate dielectric, an optional work function metal, and a gate conductor. The gate dielectric may include a high-k dielectric material. Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum. The gate conductor may be formed from any appropriate conductive metal such as, e.g., tungsten, nickel, titanium, molybdenum, tantalum, copper, platinum, silver, gold, ruthenium, iridium, rhenium, rhodium, cobalt, and alloys thereof. The gate conductor may alternatively be formed from a doped semiconductor material such as, e.g., doped polysilicon. The optional work function metal layer may include any appropriate work function metal to achieve a p-type threshold voltage shift or n-type threshold voltage shift, as appropriate. The work function metal layer can be formed of multiple sublayers to control the p-type and n-type threshold voltage.

Backside top contact placeholder 218 may be formed in vias through the bottom layer, with dielectric contact spacers 216. The dielectric contact spacers 216 may contact the bottom S/D structures 212, insulating the backside top contact placeholder 218 from the bottom S/D structures 212. The dielectric contact spacers 216 may be formed from any appropriate dielectric material, such as silicon nitride, and the backside contact placeholders may be formed by, e.g., silicon germanium.

The terms “epitaxial growth” and/or “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

Other types of material deposition that may be used herein include chemical vapor deposition (CVD), physical vapor deposition (PVD), atomic layer deposition (ALD), or gas cluster ion beam (GCIB) deposition. Some deposition processes, such as ALD, may deposit material conformally, whereas others, such as PVD or GCIB, may provide a more directional deposition. CVD may range from highly conformal to highly non-conformal depending on the formulation. The substrate holders for deposition can be static or rotating.

As used herein, the term “selective” in reference to a material removal process denotes that the rate of material removal for a first material is greater than the rate of removal for at least another material of the structure to which the material removal process is being applied.

Referring now to FIG. 3, a set of cross-sectional views is shown of a step in the fabrication of shifted stacked FETs. A wafer of alternating semiconductors is bonded to the top surface of the bottom interlayer dielectric 208 using a layer of bonding oxide 302. The alternating semiconductors include upper channel layers 304 and sacrificial layers 306, which may be formed by alternating epitaxial growth processes using, e.g., silicon and silicon germanium respectively. Once the wafer of alternating semiconductors has been formed, it can be maneuvered onto the bottom layer with a carrier wafer for bonding and the carrier wafer can then be removed from the bonded surface.

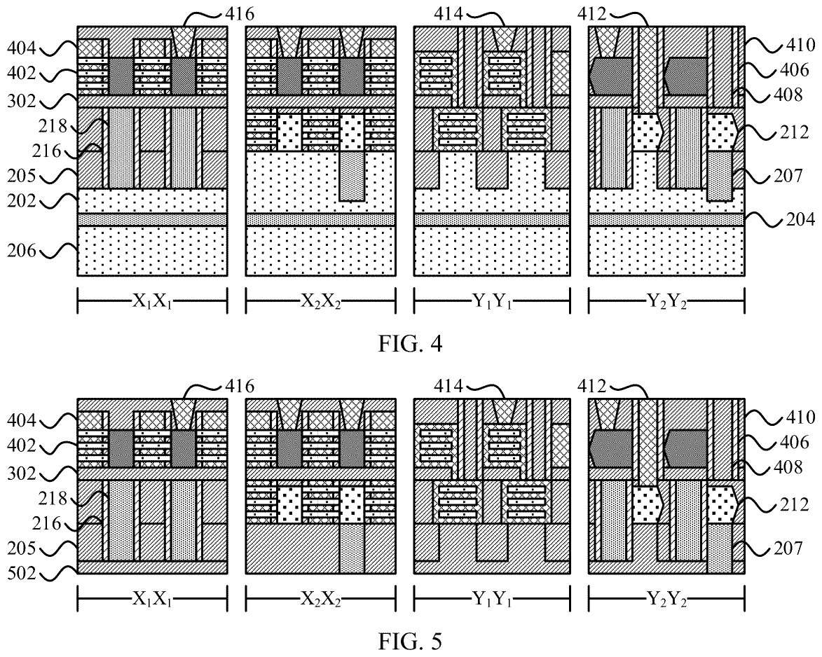

Referring now to FIG. 4, a set of cross-sectional views is shown of a step in the fabrication of shifted stacked FETs. The alternating semiconductor layers are processed to form top FETs, including top channels 402 and top gate stacks 404. The embodiments shown herein include an electrical connection between the top gate stacks 404 and the respective bottom gate stacks 214, with a via being formed through the bonding oxide 302 that is filled with conductive gate material, but it should be understood that other embodiments may keep the top FETs separate from the bottom FETs.

A gate cut may be formed by etching through the top layer, forming openings through a frontside interlayer dielectric 410 and other structures to penetrate the bonding oxide 302. The gate cut may include a bi-layer dielectric fill, including a dielectric liner 406 and a dielectric fill 408, being formed from different dielectric materials. For example, the dielectric liner 406 may be formed from silicon nitride by a conformal deposition, and the dielectric fill 408 may be formed by any appropriate deposition of silicon dioxide.

In another region, a similar process may be used to form a frontside bottom contact 412, which can provide an electrical from the front side of the device to, e.g., source/drain structures on the bottom layer. A via may be formed that penetrates through the top layer to expose a bottom S/D structure 212. The formation of the dielectric liner 406 of the gate cut can further form a liner in this via before a conductive material is deposited to form the frontside bottom contact 412. Frontside top contacts 416 can similarly be formed by etching vias into the frontside interlayer dielectric 410 to expose top S/D structures and depositing conductive material into the vias. A frontside gate contact 414 can also be formed through the frontside interlayer dielectric 410 to some of the stacked FETs. Because the top FETs and bottom FETs are stacked and connected by their gates in the depicted embodiment, the frontside gate contact 414 is electrically connected to a respective bottom FET.

At this stage, additional layers may be added to the front side of the device, such as back-end-of-line (BEOL) layers (not shown) and a carrier wafer (not shown). The BEOL layers may include conductive interconnects and vias to provide electrical connectivity to the frontside top contacts 416, the frontside gate contact 414, and the frontside bottom contact 412. The carrier wafer may be bonded to the BEOL layers so that the device can be flipped upside-down to expose the back side for further processing.

Referring now to FIG. 5, a set of cross-sectional views is shown of a step in the fabrication of shifted stacked FETs. The carrier substrate 206, the etch stop layer 204, and the semiconductor substrate 202 are etched away, exposing the backside bottom contact placeholder 207 and the backside top contact placeholder 218. A first backside interlayer dielectric 502 is deposited by any appropriate deposition process, for example depositing a dielectric material such as silicon dioxide. Excess dielectric material may be removed by a CMP process that stops on the backside bottom contact placeholder 207.

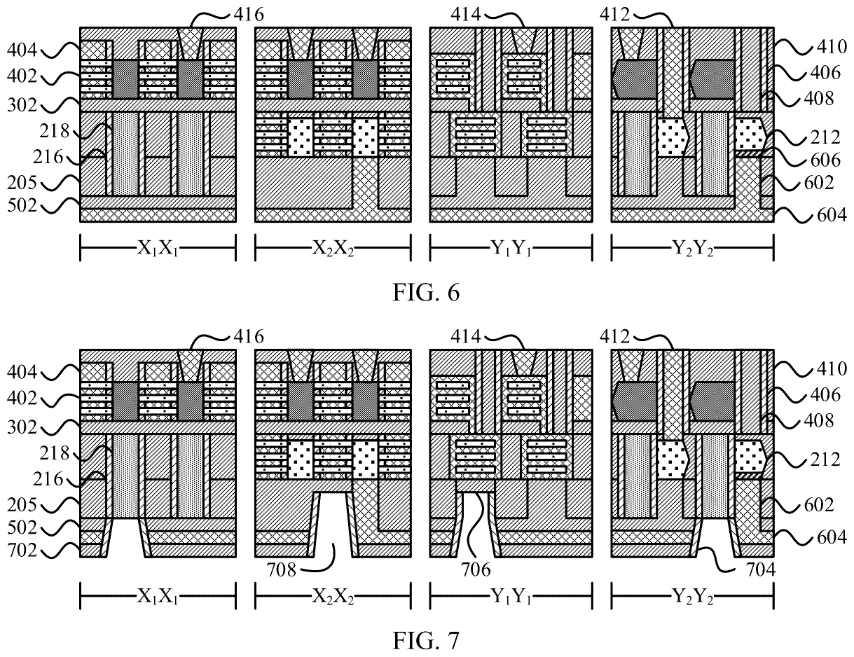

Referring now to FIG. 6, a set of cross-sectional views is shown of a step in the fabrication of shifted stacked FETs. The backside bottom contact placeholder 207 is selectively etched away, exposing the associated bottom S/D structure 212. A first silicide layer 606 may be formed on the bottom surface of the bottom S/D structure 212, for example by depositing a metal on the semiconductor material thereof and annealing. The hole through the first backside interlayer dielectric 502 is filled with conductive material, deposited by any appropriate deposition process or mixed growth processes, to form backside bottom contact 602 and backside power plane 604.

Referring now to FIG. 7, a set of cross-sectional views is shown of a step in the fabrication of shifted stacked FETs. Additional dielectric material is deposited on the backside power plane 604 to form a second backside interlayer dielectric 702. The second backside interlayer dielectric 702 should be a distinct material as compared to the first backside interlayer dielectric 502 and should be selectively etchable therewith, as well as with respect to the frontside interlayer dielectric 410. Vias are formed through the second backside interlayer dielectric 702 and the backside power plane 604 to expose the backside top contact placeholder 218. A dielectric liner 704 is formed in the via, for example by conformal deposition of silicon nitride followed by a selective anisotropic etch that removes material from horizontal surfaces.

The vias further include a backside gate via 708 that is etched through the second backside interlayer dielectric 702 and partially through the first backside interlayer dielectric 502, leaving an exposed dielectric surface 706. The backside gate via 708 may partially cut through the backside bottom contact 602, exposing a portion thereof. This etch does not touch the gate conductor. The etch of the first backside interlayer dielectric is selective and leaves the STI structures 205 in place. The dielectric liner 704 is similarly formed in the backside gate via 708, thereby electrically insulating the backside gate via 708 from the backside bottom contact 602.

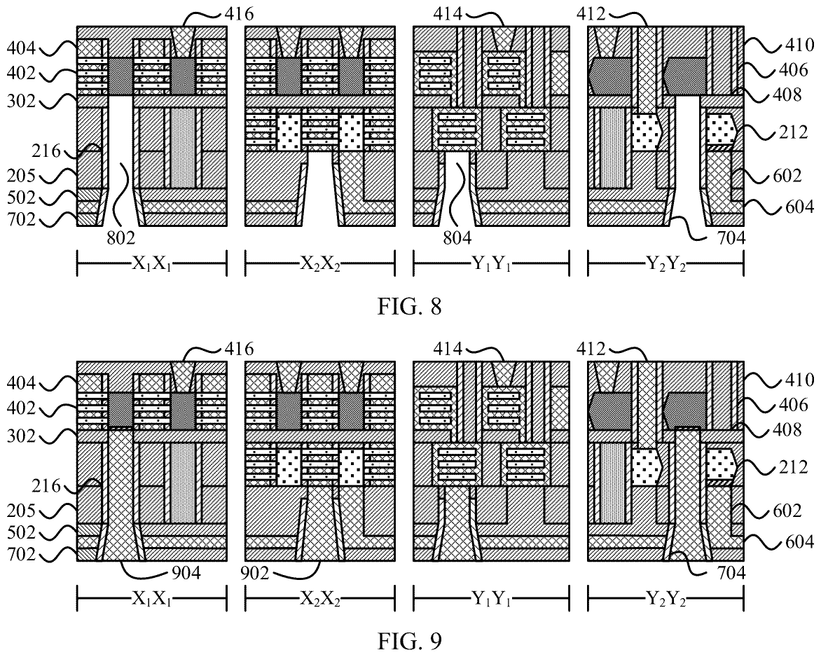

Referring now to FIG. 8, a set of cross-sectional views is shown of a step in the fabrication of shifted stacked FETs. The backside top contact placeholders 218 are selectively etched away and the bonding oxide 302 is etched through to expose the underside of a top S/D structure. The remaining exposed dielectric surface 706 in the backside gate via 708 is anisotropically etched away to expose the underside of a bottom gate. The etch opens up a backside top contact via 802 and a backside bottom gate via 804.

Referring now to FIG. 9, a set of cross-sectional views is shown of a step in the fabrication of shifted stacked FETs. Conductive material is deposited using a conformal deposition process that fills the vias 802 and 708, including along the exposed top S/D structure and the bottom gate to form a backside gate contact 902 that makes electrical contact with the exposed bottom gate and a backside top S/D contact 904 that makes electrical contact with a bottom of the top S/D structure. Excess conductive material can be removed with a CMP process that stops on the second backside interlayer dielectric 702. A second silicide layer may be formed on the exposed surface of the top S/D structure before forming the backside top S/D contact 904. In some cases a conductive liner (not shown) may be formed from titanium or titanium nitride between the backside gate contact 902 and the bottom gate stack 214.

At this stage, additional layers may be added to the back side of the device, such as backside interconnect layers (not shown). The backside interconnect layers may include conductive interconnects and vias to provide electrical connectivity to the backside gate contact 902 and the backside top S/D contact 904 and may include backside power distribution.

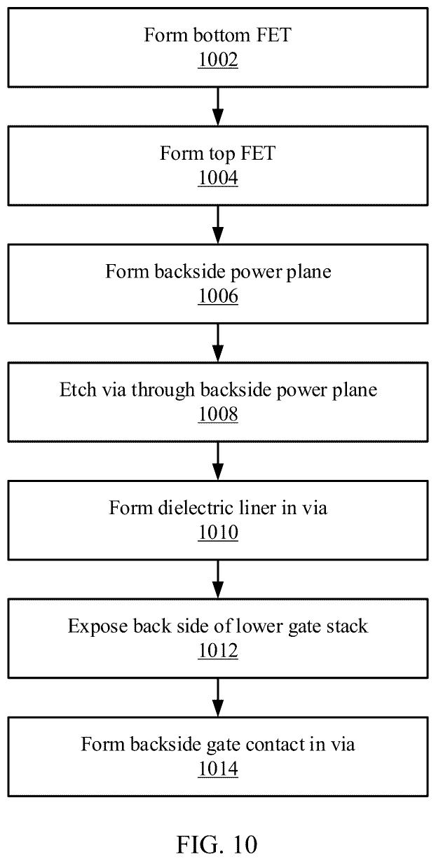

Referring now to FIG. 10, a method of forming a semiconductor device is shown. Block 1002 forms a bottom FET that includes a bottom gate stack 214 in a lower device layer. Block 1004 forms a top FET over the bottom FET, in an upper device layer, the top FET being laterally offset with respect to the bottom FET. The top FET may include a gate stack that is electrically connected to the bottom gate stack 214, or may have an electrically isolated gate stack. Any appropriate sequence of fabrication processes may be used to form the bottom FET and the top FET, as described in greater detail above.

Block 1006 forms a backside power plane 604 on a back side of the lower device layer. The backside power plane 604 may include a backside bottom contact to another FET on the lower device layer. Block 1008 then etches a backside gate via 708 through the backside power plane 604 and block 1010 forms a dielectric liner 704 on sidewalls of the via.

Block 1012 performs a further etch that penetrates the exposed dielectric surface 706 of the first backside interlayer dielectric 502 to expose the back side of the lower gate stack. Block 1014 then forms backside gate contact 902 in the backside gate contact via 804.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a backside gate contact for shifted stacked FETs (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a lower device layer that comprises a bottom transistor;
an upper device layer that comprises a top transistor positioned above and laterally offset from the bottom transistor;
a backside power plane below the lower device layer;
a backside bottom gate contact that penetrates through the backside power plane to contact a gate of the bottom transistor; and
a dielectric liner between the backside power plane and the backside bottom gate contact.

2. The semiconductor device of claim 1, further comprising a backside bottom S/D contact that electrically connects the backside power plane to a source/drain structure of the bottom transistor.

3. The semiconductor device of claim 2, wherein the dielectric liner directly contacts the backside bottom gate contact and the backside bottom S/D contact.

4. The semiconductor device of claim 1, further comprising a backside top S/D contact that penetrates through the backside power plane to contact a source/drain structure of the top transistor.

5. The semiconductor device of claim 4, further comprising a bonding layer between the lower device layer and the upper device layer, wherein the backside top S/D contact penetrates the lower device layer and the bonding layer.

6. The semiconductor device of claim 1, further comprising a first backside interlayer dielectric between the lower device layer and the backside power plane.

7. The semiconductor device of claim 6, wherein the backside bottom gate contact directly contacts the first backside interlayer dielectric in a region between the dielectric liner and the gate of the bottom transistor.

8. The semiconductor device of claim 6, further comprising a second backside interlayer dielectric below the backside power plane, formed from a material that is different from a material of the first backside interlayer dielectric.

9. The semiconductor device of claim 6, wherein the dielectric liner is formed from a material that is different from a material of the first backside interlayer dielectric.

10. A semiconductor device, comprising:
a lower device layer that comprises a bottom transistor;
an upper device layer that comprises a top transistor positioned above and laterally offset from the bottom transistor;
a first backside interlayer dielectric below the lower device layer;
a backside power plane below the first backside interlayer dielectric;
a backside bottom gate contact that penetrates through the backside power plane and the first backside interlayer dielectric to contact a gate of the bottom transistor; and
a dielectric liner directly between the backside power plane and the backside bottom gate contact.

11. The semiconductor device of claim 10, further comprising a backside bottom S/D contact that electrically connects the backside power plane to a source/drain structure of the bottom transistor.

12. The semiconductor device of claim 11, wherein the dielectric liner directly contacts the backside bottom S/D contact.

13. The semiconductor device of claim 10, further comprising a backside top S/D contact that penetrates through the backside power plane to contact a source/drain structure of the top transistor.

14. The semiconductor device of claim 13, further comprising a bonding layer between the lower device layer and the upper device layer, wherein the backside top S/D contact penetrates the lower device layer and the bonding layer.

15. The semiconductor device of claim 10, wherein the backside bottom gate contact directly contacts the first backside interlayer dielectric in a region between the dielectric liner and the gate of the bottom transistor.

16. The semiconductor device of claim 10, further comprising a second backside interlayer dielectric below the backside power plane, formed from a material that is different from a material of the first backside interlayer dielectric.

17. The semiconductor device of claim 10, wherein the dielectric liner is formed from a material that is different from a material of the first backside interlayer dielectric.

18. A semiconductor device, comprising:
a lower device layer that comprises a bottom transistor;
an upper device layer that comprises a top transistor positioned above and laterally offset from the bottom transistor;
a backside interlayer dielectric below the lower device layer;
a backside power plane below the backside interlayer dielectric;
a backside bottom gate contact that penetrates through the backside power plane and the first backside interlayer dielectric to contact a gate of the bottom transistor;
a backside top S/D contact that penetrates through the backside power plane to contact a source/drain structure of the top transistor; and
a dielectric liner directly between the backside power plane and the backside bottom gate contact.

19. The semiconductor device of claim 18, further comprising a bonding layer between the lower device layer and the upper device layer, wherein the backside top S/D contact penetrates the lower device layer and the bonding layer.

20. The semiconductor device of claim 18, wherein the backside bottom gate contact directly contacts the backside interlayer dielectric in a region between the dielectric liner and the gate of the bottom transistor.
